(19) United States
(12) Patent Application Publication
(10) Pub. No.: US 2007/0243414 A1
(43) Pub. Date: Oct. 18, 2007

(54) Positive Electrode Structure and Gallium Nitride-Based Compound Semiconductor Light-Emitting Device

(76) Inventor: Hisayuki Miki, Chiba-shi (JP)

Correspondence Address: SUGHRUE MION, PLLC, 2100 PENNSYLVANIA AVENUE, N.W., SUITE 800, WASHINGTON, DC, 20037, US

(21) Appl. No.: 11/579,961

(22) PCT Filed: May 20, 2005
(86) PCT No.: PCT/JP05/09715

§ 371 Date: Nov. 9, 2006

Related U.S. Application Data
(60) Provisional application No. 60/577,187, filed on Jun. 7, 2004.

(30) Foreign Application Priority Data
May 26, 2004 (JP) 2004-156323

(51) Int. Cl. H01L 33/00; H01L 29/43

(52) U.S. Cl. 428/699

(57) ABSTRACT

This positive electrode structure is a transparent positive electrode for a gallium nitride-based compound semiconductor light emitting device including In, the positive electrode structure includes two layers which are a contact metal layer including a thin film of at least one metal selected from the platinum group and a current diffusion layer including a thin film of metals or alloys other than the metal included in the contact metal layer and a bonding pad.

### TECHNICAL FIELD

This invention relates to a gallium nitride compound semiconductor light emitting device having a translucent positive electrode, and in particular relates to a positive electrode structure and light emitting device with minimal reduction in output when an device structure having a light emitting layer including In is employed.

The present application claims priority on Japanese Patent Application 2004-156323, filed on May 26, 2004, and U.S. Patent Application 60/577,187, filed on Jun. 7, 2004, the contents of which are incorporated herein by reference.

### BACKGROUND ART

GaN-based compound semiconductor materials have recently attracted attention as semiconductor materials for short wavelength light emitting devices. GaN-based compound semiconductors are formed on substrates composed of sapphire single crystals, various other oxides, or III-V compounds by a method such as metalloorganic chemical vapor deposition (MOCVD) or molecular beam epitaxy (MBE).

One of the characteristics of GaN-based compound semiconductor materials is having low current diffusion in the horizontal direction. Although this is thought to be due to the presence of large numbers of dislocations penetrating from the substrate to the surface in epitaxial crystals, the details of this are not fully understood. Moreover, in p-type GaN-based compound semiconductors, the resistivity is higher than the resistivity of n-type GaN-based compound semiconductors, there is hardly any horizontal spreading of current in the p layer in the case in which metal is simply deposited on the surface thereof, thereby in the case of adopting an LED structure having a pn junction, light is only emitted downward directly beneath the positive electrode.

Hence, structures have been adopted in which a translucent electrode is formed as the positive electrode, and light is emitted to an outside through the electrode. In such a structure, the electrode is provided with a function to cause current diffusion. For example, it has been proposed to deposite Ni and Au at 10 nm each on the p layer for use as the positive electrode, and carry out alloying treatment in an oxygen atmosphere to promote lower resistance of the p layer as well as form a translucent and ohmic positive electrode (see, for example, Japanese Patent No. 2803742).

In addition, it has also been proposed to form a Pt layer on the p layer for use as the positive electrode followed by heat treatment in an atmosphere including oxygen to simultaneously carry out resistance reduction and alloying treatment of the p layer (see, for example, Japanese Unexamined Patent Application, First Publication No. H11-186605).

However, since this method also involves heat treatment in an oxygen atmosphere, it has the same problems as those described above. Moreover, although the translucent electrode must be considerably thin (5 nm or less) to obtain a satisfactory translucent electrode with Pt alone, this results in an increase in the electrical resistance of the Pt layer. Thus, even if resistance of the Pt layer is reduced by heat treatment, current spreading is poor and emission of light is not uniform, leading to an increase in forward voltage (VF) as well as a decrease in emission intensity.

Moreover, it has been found that heat treatment affects the structure of semiconductor layers. Particularly, in the case of a structure in which the light emitting layer include In, a gallium nitride-based compound semiconductor crystal including In is degraded by heat, resulting in problems that a light emission output reduces and a reverse voltage lowers. And, even when initial characteristics are good, degradation due to aging tends to occur in materials which have undergone thermal hysteresis. Consequently, it is desirable that an device in which the light emitting layer includes In not be subjected to heat treatment, insofar as possible, in manufacturing processes.

### DISCLOSURE OF THE INVENTION

In order to resolve the above problems, an object of the invention is to provide a positive an electrode structure in an device structure in which a light emitting layer includes In, which does not require a heat treatment in an oxygen environment and a alloying treatment, and with satisfactory translucency, low contact resistance, and excellent current diffusion properties, as well as a semiconductor light emitting device employing this positive electrode and having high light emission efficiency.

In this invention, translucency refers to translucency with respect to light in the wavelength range from 300 to 600 nm, and does not mean colorless transparency.

The present invention provides the following inventions.

(1) A positive electrode structure as a transparent positive electrode for a gallium nitride-based compound semiconductor light emitting device including In, the positive electrode structure includes: two layers which are a contact metal layer including a thin film of at least one metal selected from the platinum group and a current diffusion layer including a thin film of metals or alloys other than the metal included in the contact metal layer; and a bonding pad.

(2) The positive electrode structure according to (1), wherein a thickness of the contact metal layer is from 0.1 to 7.5 nm.

(3) The positive electrode structure according to (1), wherein a thickness of the contact metal layer is from 0.1 to 5 nm.

(4) The positive electrode structure according to (1), wherein a thickness of the contact metal layer is from 0.5 to 2.5 nm.

(5) The positive electrode structure according to any one of (1) to (4), wherein the platinum group metal included in the contact metal layer is at least one metal of platinum, iridium, rhodium, and ruthenium.

(6) The positive electrode structure according to any one of (1) to (5), wherein the contact metal layer includes platinum.

(7) The positive electrode structure according to any one of (1) to (6), wherein the current diffusion layer is a thin film of at least one metal selected from gold, silver, and copper, or a thin film of an alloy including at least one metal selected therefrom.

(8) The positive electrode structure according to any one of (1) to (7), wherein the current diffusion layer is of gold.

(9) The positive electrode structure according to any one of (1) to (8), wherein a thickness of the current diffusion layer is from 1 to 20 nm.

(10) The positive electrode structure according to any one of (1) to (8), wherein a thickness of the current diffusion layer is 10 nm or less.

(11) The positive electrode structure according to any one of (1) to (8), wherein a thickness of the current diffusion layer is from 3 to 6 nm.

(12) A gallium nitride-based compound semiconductor light emitting device includes: a light emitting layer with a quantum-well structure having a gallium nitride-based compound semiconductor including In; and the positive electrode structure according to any one of (1) to (11).

(13) The gallium nitride-based compound semiconductor light emitting device according to (12), wherein the light emitting layer is a multiple-quantum-well structure having a plurality of well layers and a plurality of barrier layers.

According to this invention, by using, as an electrode of a light emitting device having a light emitting layer containing In, a translucent electrode comprising only metals, without performing heat treatment in fabrication processes, a light emitting device can be manufactured with minimal aging degradation and without tending toward lowered light emission intensity or lowering of the peak inverse voltage.

### BRIEF DESCRIPTION OF THE DRAWINGS

FIG. 1 is a schematic drawing showing a cross-sectional structure of a compound semiconductor light emitting device of this invention.

FIG. 2 is a schematic drawing showing a cross-sectional structure of a compound semiconductor light emitting device of an embodiment.

FIG. 3 is a schematic drawing showing a plane view of a compound semiconductor light emitting device of an embodiment.

FIG. 4 shows a cross-sectional structure of the light emitting layer of an embodiment.

### BEST MODE FOR CARRYING OUT THE INVENTION

The following provides an explanation of preferred embodiments of the present invention with reference to the drawings. However, the present invention is not limited to each of the following embodiments, and for example, the constituents of these embodiments may be suitably combined.

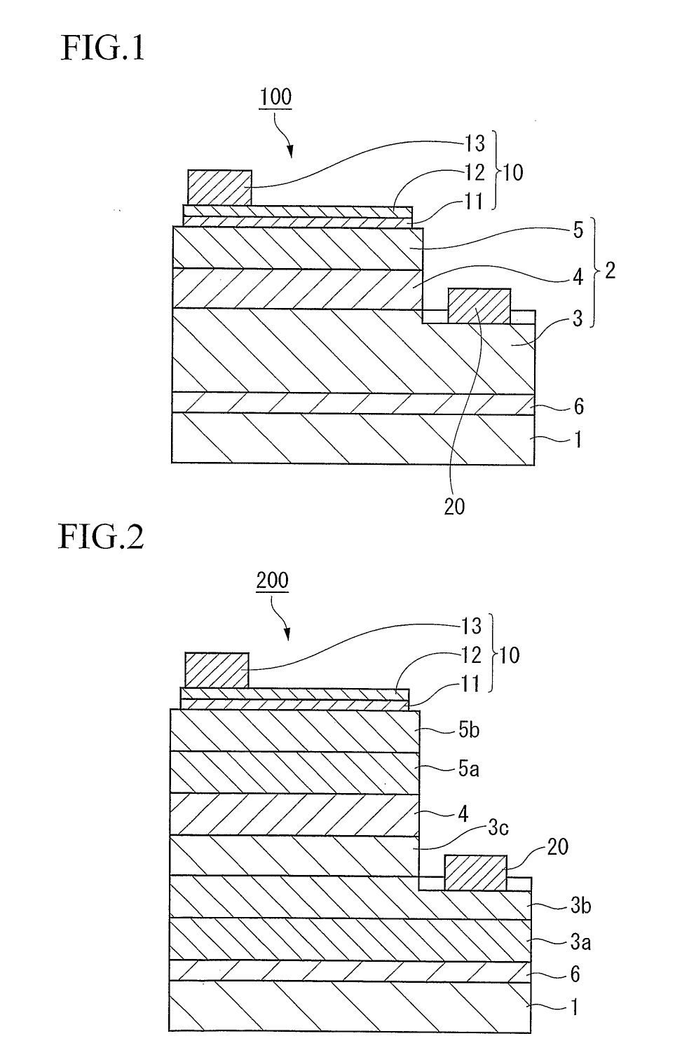

FIG. 1 is a schematic drawing showing the cross-sectional structure of a light emitting device having a translucent positive electrode of this invention. In the compound semiconductor light emitting device 100 of this invention, a GaN-based compound semiconductor layer 2 is formed on a substrate 1 interposed with a buffer layer 6 between them, and a translucent positive electrode 10 of this invention is formed thereon.

The GaN-based compound semiconductor layer 2 is composed with a hetero junction structure including, for example, an n-type semiconductor layer 3, a light emitting layer 4, and a p-type semiconductor layer 5. The light emitting layer 4 includes In. The light emitting layer 4 may have a multiple-quantum-well structure including a well layer having In and a barrier layer not having In.

A negative electrode 20 is formed in a portion of the n-type semiconductor layer 3, and the translucent positive electrode 10 is formed in a portion of the p-type semiconductor layer 5.

In addition, the translucent positive electrode 10 has three layers consisting of a contact metal layer 11, a current diffusion layer 12, and a bonding pad layer 13.

Small contact resistance with the p-type semiconductor layer 5 is essential for the required performance of the contact metal layer 11. Moreover, superior optical transmissivity is required for face-up mounting type light emitting devices in which light from the light emitting layer 4 is extracted from the electrode side.

From the standpoint of obtaining satisfactory contact resistance without performing heat treatment, a material of the contact layer 11 is preferably a platinum group metal such as platinum (Pt), ruthenium (Ru), osmium (Os), rhodium (Rh), iridium (Ir), palladium (Pd), or similar. Among these, Pt is particularly preferable since Pt has a high work function and enables satisfactory Ohmic contact even with a p-type GaN-based compound semiconductor which is not subjected to high-temperature heat treatment and has comparatively high resistivity.

In the case in which the contact metal layer 11 includes a platinum group metal, it is necessary to make its thickness extremely thin from the viewpoint of optical transmissivity. It is preferable that the thickness of the contact metal layer is within a range from 0.1 to 7.5 nm. In the case in which the thickness is less than 0.1 nm, it is difficult to obtain a stable thin film. In the case in which the thickness exceeds 7.5 nm u, the translucence declines, and so a thickness of 5 nm or less is preferable. In addition, the thickness of the contact metal layer 11 is particularly preferably 0.5 to 2.5 nm in consideration of deposition stability and a decrease in the translucency caused by a subsequent deposition of the current diffusion layer 12.

However, since reducing the thickness of the contact metal layer 11 in this manner causes an increase in the electrical resistance in the planar direction of the contact metal layer, and the p layer has a comparatively high resistance, the current flows only in a periphery of the bonding pad layer 13 serving as a current injection area. As a result, light emission pattern is not uniform and emission output decreases.

Therefore, by arranging the current diffusion layer 12 which is composed of a metal thin film having high optical transmissivity and high conductivity on the contact metal layer 11 as a means of compensating for the current diffusivity of the contact metal layer 11, the current is able to spread uniformly without significantly impairing a low contact resistance and a optical transmissivity of the platinum group metal. As a result, a light emitting device having a high emission output can be obtained.

The current diffusion layer 12 includes a thin film of metals or alloys other than the metal included in the contact metal layer 11.

A material of the current diffusion layer 12 is preferably a metal having high conductivity, such as a metal selected from the group consisting of gold (Au), silver (Ag), or copper (Cu) and an alloy that includes at least one of these metals. Gold is particularly preferable due to its high optical transmissivity when formed into a thin film.

A thickness of the current diffusion layer 12 is preferably 1 to 20 nm. In the case in which the thickness is less than 1 nm, current diffusion effects are not adequately demonstrated. In the case in which the thickness exceeds 20 nm, an optical transmissivity of the current diffusion layer 12 decreases remarkably, resulting in the risk of a decrease in emission output. A thickness of 10 nm or less is more preferable. Moreover, when the thickness is made to be within a range from 3 to 6 nm, a balance between the effects of an optical transmissivity and a current diffusion of the current diffusion layer 12 becomes optimal, thereby, together with the aforementioned contact metal layer 11, high-output emission that is uniform over the entire surface of the positive electrode can be obtained.

There are no particular limitations on the method used to deposit the contact metal layer 11 and the current diffusion layer 12, and a known method such as vacuum deposition or sputtering can be used. Among these, a vacuum deposition method which is attended by minimal thermal damage is appropriate as a method for forming an electrode in a device having a light-emission layer 4 including In.

Various structures using various materials are known for the bonding pad layer 13 that composes the bonding pad area, and these known structures and materials can be used without any particular limitations. However, it is desirable to use a material having satisfactory adhesion with the current diffusion layer 12, and it is necessary that a thickness be sufficiently thick so as not to impart damage to the contact metal layer 11 or the current diffusion layer 12 by a stress generated during bonding. In addition, an uppermost layer preferably includes a material having satisfactory adhesion with a bonding ball.

The greatest advantage of a translucent electrode including only metals such as that proposed in this invention is the ability to form the electrode without employing heat treatment in fabrication processes. Absence of the heat treatment in fabrication processes is extremely advantageous for suppressing an accumulation of thermal damage to the light emitting layer 4 in a well-known gallium nitride-based compound semiconductor light emitting device of the prior art having the light emitting layer 4 including In. When using conventional translucent electrodes with a structure containing an oxide layer which cannot be formed without passing through a heat treatment process, and also translucent electrodes of a metal which are subjected to heat treatment in order to obtain an Ohmic contact, a thermal decomposition of crystalline materials occurs in the light emitting layer 4 of InGaN or other material containing In, so that metallized portions are observed. And even when clear indications of such damage are not observed, aging has resulted in the damage; but when an electrode which has not passed through a heat treatment process is employed, such problems are avoided.

This is a generally observed as an advantage for the gallium nitride-based compound semiconductor light emitting devices having the light emitting layer 4 including In. Further, in a quantum-well-structure in which the InGaN layer is made thin and a lattice strain is present, this advantage is particularly pronounced. The advantage of suppressing damage to the light emitting layer 4 is still more prominent in the case in which a multiple-quantum-well structure is employed.

As the substrate 1, a well-known substrate material may be used without particular limitations, such as sapphire single crystal (Al₂O₃: A plane, C plane, M plane, and R plane), spinel single crystal (MgAlO₄), ZnO single crystal, LiAlO₂ single crystal, LiGaO₂ single crystal, MgO single crystal, and other oxide single crystal substrates, Si single crystal, SiC single crystal, GaAs single crystal, AlN single crystal, GaN single crystal, and ZrB₂ and other boride single crystal substrates. Here, there are no particular limitations on a plane direction of the substrate. In addition, substrates having a surface exactly oriented to a crystal plane, or an off-angle may also be used.

Various structures are known for the n-type semiconductor layer 3, the light emitting layer 4, and the p-type semiconductor layer 5, and these well-known structures can be used without any limitations in particular. In particular, although a typical concentration is used for the carrier concentration of the p-type semiconductor layer 5, the translucent positive electrode of the present invention can also be applied to as an electrode for the p-type semiconductor layers having comparatively low carrier concentrations, for example, a carrier concentration of about 1×10¹⁷ cm⁻³.

As the gallium nitride-based compound semiconductor that forms the light emitting device, semiconductors with various compositions represented by the general formula AlₓIn_{y}Ga_{1-x-y}N (0≦x≦1, 0≦y<1, 0≦x+y<1) are well-known, and also, as the gallium nitride-based compound semiconductors that form the n-type semiconductor layer 3 and p-type semiconductor layer 5 in this invention, semiconductors with various compositions represented by the general formula AlₓIn_{y}Ga_{1-x-y}N (0≦x<1, 0≦y<1, 0≦x+y<1) can be used without particular limitations. As the gallium nitride-based compound semiconductor that forms the light emitting layer 4, semiconductors represented by the general formula AlₓIn_{y}Ga_{1-x-y}N (0≦x<1, 0≦y<1, 0<x+y<1) can be used without particular limitations.

There are no particular limitations on a growth method of these gallium nitride-based compound semiconductors, and all known methods for growing group III nitride semiconductors can be applied, examples of which include metalloorganic chemical vapor deposition (MOCVD), hydride vapor phase epitaxy (HVPE), and molecular beam epitaxy (MBE). A preferable growth method is MOCVD from the viewpoint of a film thickness controllability and a mass production.

In the MOCVD method, hydrogen (H₂) or nitrogen (N₂) is used as a carrier gas, trimethyl gallium (TMG) or triethyl gallium (TEG) is used as a Ga source serving as a group III material, trimethyl aluminum (TMA) or triethyl aluminum (TEA) is used as an Al source, trimethyl indium (TMI) or triethyl indium (TEI) is used as an In source, and ammonia (NH₃) or hydrazine (N₂H₄) is used as a N source serving as a group V material. In addition, examples of dopants used as an n type include Si material of monosilane (SiH₄) or disilane (Si₂H₆) and a Ge material of germane (GeH₄), while examples of dopants used for the p type include a Mg material of bis-cyclopentadienyl magnesium (Cp₂Mg) or bis-ethylcyclopentadienyl magnesium ((EtCp)₂Mg).

In order to form the negative electrode 20 in contact with the n-type semiconductor layer 3 of the gallium nitride-based compound semiconductor in which the n-type semiconductor layer 3, the light emitting layer 4, and the p-type semiconductor layer 5 are deposited in succession on the substrate, portions of the light emitting layer 4 and the p-type semiconductor layer 5 are removed to expose the n-type semiconductor layer 3. Subsequently, the translucent positive electrode of this invention is formed on the remaining p-type semiconductor layer 5, and a negative electrode 20 is then formed on the exposed n-type semiconductor layer 3. As the negative electrode 20, various compositions and structures for negative electrodes are well known, and these well-known negative electrodes can be used without any limitations in particular.

In this invention, it is a prerequisite that indium (In) is included in the light emitting layer (active layer) 4. The light emitting layer 4 may include a single layer of InGaN or similar, or may have a quantum-well structure; the advantageous results of this invention are particularly prominent when the quantum-well structure is adopted.

As the quantum-well structure, a single-quantum-well structure including a single layer may be used; however a multiple-quantum-well structure in which a plurality of well layers which are active layers and barrier layers are deposited in alternation is preferable because a light emission output is improved. A preferred number of depositions is from three to approximately ten, and a number from three to six is still more preferable. In the case of the multiple-quantum-well structure, there is no need for all the well layers (active layers) to include a thick film portion and a thin film portion; moreover, dimensions and area ratios of the thick film portion and the thin film portion may be changed for each layer. Here, in this specification, in the case of the multiple-quantum-well structure, whole of the combination of the well layer (active layer) and the barrier layer is called the light emitting layer.

A film thickness of a barrier layer is preferably 70 Å or greater, and the thickness is still more preferably 140 Å or greater. In the case in which the film thickness of the barrier layer is thin, planarization of an upper surface of the barrier layer is impeded, resulting in lowering a light emission efficiency and aging characteristics. In the case in which the film thickness is too thick, a forward driving voltage is increased and an emitted light intensity is decreased. Consequently, the thickness of the barrier layer is preferably 500 Å or less.

In the case of the multiple-quantum-well structure, the barrier layers can be formed from InGaN with an In composition ratio lower than that of the InGaN forming the well layer (active layer) as well as GaN and AlGaN. Among these, GaN is preferable.

When the active layers is composed with the multiple-quantum-well structure and are undoped, a structure can be employed in which the well layer includes a thick area and a thin area. By employing such a structure for the well layer, forward driving voltages can be lowered.

Such a structure can be formed by growing the well layer at comparatively low temperatures from 600° C. to 900° C., followed by subjecting a heat-up process with a growth stopped.

When the active layer is doped with Si, as the dopant source, an organic silicon material as well as the well-known silane (SiH₄) and disilane (Si₂H₆) may be used. Silane (SiH₄) and disilane (Si₂H₆) may be supplied as gases of which purity is 100%, however from the standpoint of safety, it is preferable to supply diluted gases of such materials from tanks.

Similarly, when the active layer is doped with Ge, an organic germanium material as well as the well-known germane (GeH₄) may be used as the dopant source. Germane (GeH₄) may be supplied as a gas of which purity is 100%, however from the standpoint of safety, it is preferable to supply a diluted gas of such material from a tank.

When the active layer is doped an n-type dopant, whole portions may be doped, or only a portion of it may be doped. In particular, in a configuration which adopts the quantum-well structure, in the case in which the barrier layer is doped with the n-type dopant, there is the advantage that the forward driving voltage of the device is lowered, therefore the barrier layer is preferably doped with the n-type dopant. In this case, only a portion of the barrier layer may be doped, as well as whole portions of the barrier layer may be doped. In particular, by selectively doping an area immediately below the well layer, both a high output and a low forward driving voltage can be achieved simultaneously.

As a concentration for doping with an n-type dopant, a concentration of 5×10¹⁶ cm⁻³ or higher, and equal to or less than 1×10¹⁹ cm⁻³ is satisfactory. In the case in which the concentration is lower than this, the reduction in the forward driving voltage does not appear, and in the case in which the concentration is higher, the crystallinity and flatness are degraded. It is still more preferable that the concentration be equal to or greater than 1×10¹⁷ cm⁻³ and equal to or less than 5×10¹⁸ cm⁻³, and most preferable that the concentration be equal to or greater than 1×10¹⁷ cm⁻³ and equal to or less than 1×10¹⁸ cm⁻³.

It is preferable that an n cladding layer be provided between the contact layer and the light emitting layer, because lowering of flatness occurring in the uppermost surface of the n contact layer can be prevented. The n cladding layer can be formed from AlGaN, GaN, InGaN or similar, however when InGaN is used, it is of course preferable that a composition be employed with a band gap larger than the band gap of the InGaN of the active layer. A carrier concentration in the n cladding layer may be the same as that in the n contact layer, or may be larger or smaller. In order to improve the crystallinity of the active layer formed thereon, it is preferable that a growth rate, a growth temperature, a growth pressure, a doping amount, and other growth conditions be adjusted appropriately to obtain a surface with high flatness.

The n cladding layer may be formed by alternately depositing layers with different compositions and lattice constants a plurality of times. In this case, in addition to the composition of the layers deposited, the dopant amount, film thickness, and other parameters may also be changed.

### EXAMPLE

Next, the following provides a more detailed explanation of the present invention through its embodiments, however the present invention is not limited to these embodiments.

### Example

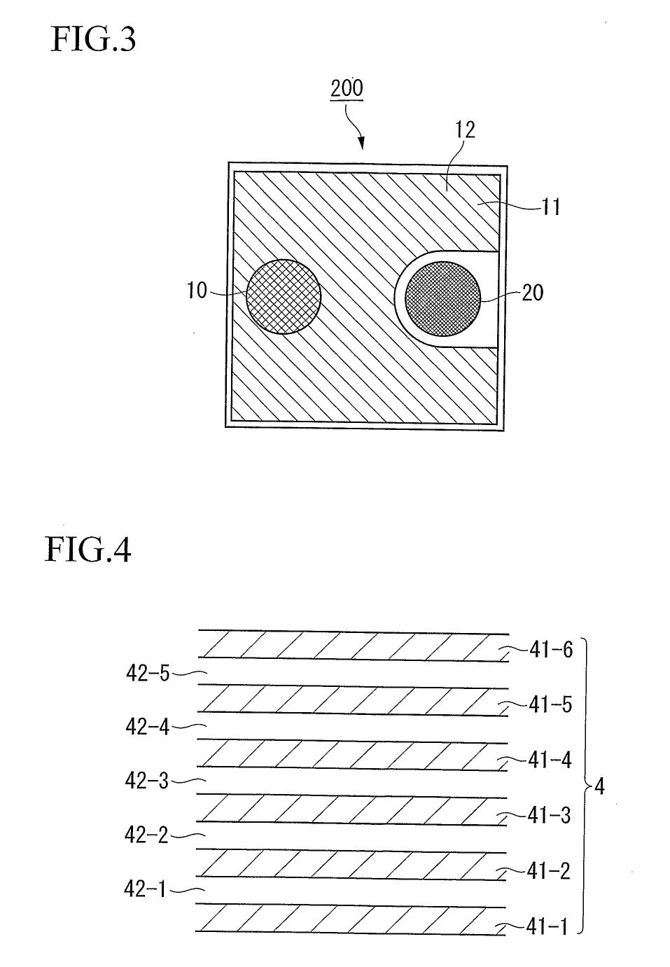

FIG. 2 is a schematic drawing of a cross-section of a gallium nitride-based compound semiconductor light emitting device 200 produced in the present example, and FIG. 3 is a schematic drawing of its overhead view. A gallium nitride-based compound semiconductor is formed by depositing in order on a sapphire substrate 1 with a buffer layer 6 of AlN intervening, a base layer 3a composed of undoped GaN having a thickness of 8 μm; a Ge-doped n-type GaN contact layer 3b having a thickness of 2 μm; an n-type In_{0.1}Ga_{0.9}N cladding layer 3c having a thickness of 0.03 μm; a light emitting layer 4 with a multiple-quantum-well structure formed by depositing a Si-doped GaN barrier layer having a thickness of 16 nm and a In_{0.2}Ga_{0.8}N well layer having a thickness of 3 nm five times and finally providing a barrier layer; a Mg-doped p-type Al_{0.07}Ga_{0.93}N cladding layer 5a having a thickness of 0.01 μm; and a Mg-doped p-type AlGaN contact layer 5b having a thickness of 0.15 μm. A positive electrode 10 composed of a Pt contact metal layer 11 having a thickness of 1.5 nm, an Au current diffusion layer 12 having a thickness of 5 nm, and an Au/Ti/Al/Ti/Au five-layer-structure (with layers of respective thicknesses 50/20/10/100/200 nm) bonding pad layer 13 are formed on the p-type AlGaN contact layer 5b. The cross-sectional structure of the light emitting layer 4 with a multiple-quantum-well structure is shown in FIG. 4. In the figure, 41-1 to 41-6 are barrier layers, and 42-1 to 42-5 are well layers.

Next, a Ti/Au double-layer negative electrode 20 is formed on the n-type GaN contact layer 3b to obtain a light emitting device in which a light emission face is on a semiconductor side. The plane-view shapes of the positive electrode 10 and the negative electrode 20 are as shown in FIG. 3.

In this light emitting device structure, a carrier concentration in the n-type GaN contact layer 3b was 5×10¹⁸ cm⁻³, an amount of doped Si in the GaN barrier layer is 1×10¹⁸ cm⁻³, a carrier concentration in the p-type AlGaN contact layer 5b was 5×10¹⁸ cm⁻³, and an amount of doped Mg in the p-type AlGaN cladding layer 5a was 5×10¹⁹ cm⁻³.

Deposition of the gallium nitride-based compound semiconductor layer was performed by the MOCVD method under ordinary conditions well-known in this technical field. The positive electrode 10 and the negative electrode 20 were formed by the following procedures.

Initially, reactive ion etching was used to expose a portion of the n-type GaN contact layer 3b on which the negative electrode was to be formed using the following procedure.

First, an etching mask was formed on the p-type semiconductor layer 5b. The procedure for formation was as follows. After uniformly coating a resist over an entire surface, the resist was removed over a region larger than a periphery of the positive electrode region using a known lithography technology. The substrate was then placed in a vacuum deposition device, and Ni and Ti were deposited at film thicknesses of about 50 nm and 300 nm, respectively, by an electron beam method at a pressure of 4×10⁻⁴ Pa. The metal film other than the positive electrode region was then removed along with the resist by a liftoff technology.

Next, the semiconductor deposited substrate was then placed on an electrode in an etching chamber of a reaction ion sputtering device, and after reducing a pressure in the etching chamber to 10⁻⁴ Pa, Cl₂ gas as an etching gas was fed into the chamber and etching was carried out until the n-type GaN contact layer 3b was exposed. Following etching, the deposited substrate 1 was taken out of the reaction ion etching device and the etching mask was removed with nitric acid and hydrofluoric acid.

Next, a well-known lithographic technique and lift-off technique were used to form a contact metal layer 11 of Pt and a current diffusion layer 12 of Au on only the area for formation of the positive electrode on the p-type AlGaN contact layer 5b. In forming the contact metal layer 11 and the current diffusion layer 12, first the substrate with gallium nitride-based compound semiconductor layer formed on top was placed in a vacuum deposition device, and at first Pt at 1.5 nm and secondary Au at 5 nm were deposited on the p-type AlGaN contact layer 5b. After taking out of the vacuum chamber, the deposited substrate was treated in accordance with a known procedure ordinarily referred to as a liftoff, after which a first layer including Au, a second layer including Ti, a third layer including Al, a fourth layer including Ti, and a fifth layer including Au were sequentially deposited on a portion of the current diffusion layer 12 to form a bonding pad layer 13 using the same procedure. In this way, a positive electrode 10 was formed on the p-type AlGaN contact layer 5b.

The positive electrode 10 formed by this method exhibited translucence, and had an optical transmissivity of 60% in a 470 nm wavelength range. Here, the optical transmissivity was measured using a sample in which the same contact metal layer and the current diffusion layer as those described above were formed to sizes for use in optical transmissivity measurement.

Next, the negative electrode 20 was formed on the exposed n-type GaN contact layer 3b according to the following procedure. After uniformly coating a resist over an entire surface, the resist was removed from a region where the negative electrode was formed on the exposed n-type GaN contact layer using a known lithography technology to form the negative electrode composed of Ti at 100 nm and Au at 200 nm in order from the semiconductor side using a routinely used vacuum deposition. The resist was subsequently removed by a known method.

By then grinding and polishing a rear surface of the substrate, the wafer on which the positive electrode 10 and the negative electrode 20 were thus formed was reduced in thickness to 80 μm, and a laser scriber was used to draw scribe lines from the semiconductor layered side, followed by breaking to obtain chips 350 μm on a side. These chips were then subjected to forward-direction voltage measurements at a current of 20 mA, applied using probes, obtaining a result of 2.9 V.

Then, a chip was mounted in a TO-18 package and a tester was used to measure the light emission output, and the light emission output at an applied current of 20 mA was found to be 6 mW. The sample was then left mounted in the TO-18 package and a current of 30 mA was applied for 100 hours continuously, and the light emission characteristic and electrical characteristics were measured. No change was observed in the light emission output or in the reverse voltage.

### Comparative Example 1

Except for employing a conventional Au/NiO structure for the electrode, a gallium nitride-based compound semiconductor light emitting device was produced in the same manner as Example. When forming the Au/NiO translucent electrode, heat treatment was performed at 450° C. in an oxygen environment. The forward-direction voltage and light emission output of this light emitting device were 2.9 V and 3.7 mW respectively. Upon observing the manner of light emission using a microscope, dark spots were observed in places. This is thought to indicate that degradation had occurred in the light emitting layer due to the heat treatment performed during a production of the translucent electrode.

### Comparative Example 2

Except for employing a structure of Pt only for the electrode and a heat treatment was performed, a gallium nitride-based compound semiconductor light emitting device was produced in the same manner as Example. The forward-direction voltage and the light emission output of this light emitting device were 2.9 V and 4.5 mW respectively. Upon passing a 30 mA current through this sample continuously for 100 hours in an aging test, the reverse voltage at a reverse current of 10 μA which had been 20 V or higher before the test, fell to 5 V after the test. The reason is thought to indicate a damage to the light emitting layer accumulated in the course of the heat treatment performed during a production of the translucent electrode.

### INDUSTRIAL APPLICABILITY

An electrode for gallium nitride-based compound semiconductor light emitting devices provided by this invention is useful as the positive electrode of a light-transmitting gallium nitride-based compound semiconductor light emitting device.

1. A positive electrode structure as a transparent positive electrode for a gallium nitride-based compound semiconductor light emitting device including In, the positive electrode structure comprising:
two layers which are a contact metal layer including a thin film of at least one metal selected from the platinum group and a current diffusion layer including a thin film of metals or alloys other than the metal included in the contact metal layer; and
a bonding pad.

2. The positive electrode structure according to claim 1, wherein a thickness of the contact metal layer is from 0.1 to 7.5 nm.

3. The positive electrode structure according to claim 1, wherein a thickness of the contact metal layer is from 0.1 to 5 nm.

4. The positive electrode structure according to claim 1, wherein a thickness of the contact metal layer is from 0.5 to 2.5 nm.

5. The positive electrode structure according to claim 1, wherein the platinum group metal included in the contact metal layer is at least one metal of platinum, iridium, rhodium, and ruthenium.

6. The positive electrode structure according to claim 1, wherein the contact metal layer includes platinum.

7. The positive electrode structure according to claim 1, wherein the current diffusion layer is a thin film of at least one metal selected from gold, silver, and copper, or a thin film of an alloy including at least one metal selected therefrom.

8. The positive electrode structure according to claim 1, wherein the current diffusion layer is of gold.

9. The positive electrode structure according to claim 1, wherein a thickness of the current diffusion layer is from 1 to 20 nm.

10. The positive electrode structure according to claim 1, wherein a thickness of the current diffusion layer is 10 nm or less.

11. The positive electrode structure according to claim 1, wherein a thickness of the current diffusion layer is from 3 to 6 nm.

12. A gallium nitride-based compound semiconductor light emitting device, comprising: a light emitting layer with a quantum-well structure having a gallium nitride-based compound semiconductor including In; and
the positive electrode structure according to claim 1.

13. The gallium nitride-based compound semiconductor light emitting device according to claim 12, wherein the light emitting layer is a multiple-quantum-well structure having a plurality of well layers and a plurality of barrier layers.
